(19) United States
(12) Patent Application Publication
(10) Pub. No.: US 2024/0195053 A1
(43) Pub. Date: Jun. 13, 2024

(54) MEANDER EMBEDDING SECTOR ANTENNA FOR SERIES SUPERCONDUCTING DETECTORS

(71) Applicants: Nantong University, Nantong (CN); Nantong Research Institute for Advanced Communication Technologies Co.,Ltd., Nantong (CN)

(72) Inventors: Mei Yu, Nantong (CN); Jin Shi, Nantong (CN); Yongjie Yang, Nantong (CN); Kai Xu, Nantong (CN)

(21) Appl. No.: 18/326,040

(22) Filed: May 31, 2023

(30) Foreign Application Priority Data
Dec. 12, 2022 (CN) 202211598083X

(51) Int. Cl. H01Q 1/36; H01P 1/02; H01Q 21/00

(52) U.S. Cl. CPC H01Q 1/364; H01P 1/02; H01Q 21/0006

(57) ABSTRACT

A meander embedding sector traveling-wave antenna for series superconducting detectors is provided, including: a detector array, a meander metal layer, a pair of bend-line metal layers, and a pair of sector metal layers. The detector array is individually connected in the meander metal layer and the pair of bend-line metal layers; the pair of bend-line metal layers is correspondingly connected to the pair of sector metal layers; and the pair of sector metal layers is disposed symmetrically centered on the detector array. The antenna improves working bandwidth of THz antenna and completes low-impedance matching between a single antenna and each series Josephson junction embedded in the antenna. The embedding meander can be connected to a plurality of low-impedance detectors, and performance of the antenna is not influenced while target impedance matching is completed. And the working bandwidth of the THz antenna embedded with the series detectors is increased.

### TECHNICAL FIELD

The disclosure relates to the field of wireless communication and superconducting technologies, particularly to a wideband antenna for series devices with low impedances, such as superconducting Josephson junctions.

### BACKGROUND

In order to meet people requirements for a high rate of wireless network, the fifth generation mobile communication (5G) is published in Nov. 2019. A data transmission rate of 5G is far higher than that of previous cellular network, and a maximum rate can reach 10 Gigabytes per second (Gbit/s), which is 100 times faster than that of previous 4G long-term evolution (LTE) cellular network. It is urgent for a research on the sixth generation mobile communication (6G), and the 6G focuses on terahertz (THz) wireless communication technology. When the THz technology is applied into practical, signal detection and signal reception are critical issues. Ultra-sensitive THz detectors face huge challenges due to severe atmospheric attenuation in THz bands. A low-temperature superconducting hot-electron bolometer and a superconductor-insulator-superconductor (SIS) detector are the most sensitive THz detectors heretofore. On the other hand, high-temperature superconducting YBa₂Cu₃O_{7-δ} (YBCO) is widely concerned because it can detect the signal above 1 THz. However, an impedance of the superconducting component is quite low. For example, a normal resistance of a superconducting Josephson junction made from YBCO is at a range of 1 omega(Ω)to 40 Ω, but a traditional antenna has no such matched low impedance.

Series Josephson junctions may increase an impedance of the component, thereby achieving impedance matching with a coupled antenna. The impedance matching between the single antenna and the each series Josephson junctions embedded in the antenna becomes a research hotspot recently. However, the embedment of the series structure under multi-source excitation should have no influence on the performance of the antenna. At present, when a THz antenna is actually applied to the series Josephson junctions, the THz antenna works in a resonant mode, and mostly belongs to the antenna with a narrow bandwidth, resulting in narrow working frequency of the THz detectors, thereby greatly limiting the development of THz communication. In order to improve the working bandwidth of the THz detectors, it is necessary to propose a broadband antenna suitable for the series detectors.

### SUMMARY

In view of the above technical problems in the related art, the disclosure provides a meaner embedding sector antenna for series superconducting detectors. In this antenna, the superconducting Josephson junctions are inserted in the center of the meander to form a series structure. An objective of the disclosure is to improve working bandwidth of a terahertz (THz) antenna and complete low-impedance matching between the single antenna and each Josephson junction in series embedded in the antenna.

In order to achieve the above objective, a technical solution provided by the disclosure is as follows.

A sector antenna with traveling-wave mode, combining a meander series of superconducting Josephson junction detectors is provided, including: a detector array, a meander metal layer, a pair of bend-line metal layers, and a pair of sector metal layers. The detector array is individually connected in the meander metal layer and the pair of bend-line metal layers; the pair of bend-line metal layers is correspondingly connected to the pair of sector metal layers; and the sector traveling-wave antenna is disposed symmetrically centered on the detector array.

In an embodiment of the disclosure, the detector array includes a first detector, a second detector, a third detector, a fourth detector, a fifth detector, a sixth detector, and a seventh detector; and the meander metal layer includes a first meander, a second meander, a third meander, a fourth meander, a fifth meander and a sixth meander. An end of the first detector is connected to an end of the first meander, and another end of the first meander is connected to an end of the second detector; another end of the second detector is connected to an end of the second meander, and another end of the second meander is connected to an end of the third detector; another end of the third detector is connected to an end of the third meander, and another end of the third meander is connected to an end of the fourth detector; another end of the fourth detector is connected to an end of the fourth meander, and another end of the fourth meander is connected to an end of the fifth detector; another end of the fifth detector is connected to an end of the fifth meander, and another end of the fifth meander is connected to an end of the sixth detector; another end of the sixth detector is connected to an end of the sixth meander, and another end of the sixth meander is connected to an end of the seventh detector; and another end of the first detector and another end of the seventh detector are respectively connected to the bend-line metal layers in the pair of bend-line metal layers.

In an embodiment of the disclosure, each of the first meander to the sixth meander is a concave meander; and lengths and widths of the first meander to the sixth meander are unequal to one another.

In an embodiment of the disclosure, the lengths of the first meander to the sixth meander are configured to be adjusted to adjust active impedances of the first meander to the sixth meander and to complete target impedance matching with the first detector to the seventh detector.

In an embodiment of the disclosure, an impedance of each of the first detector to the seventh detector is 15 omegas(Ω).

Compared with the related art, the meander embedding sector traveling-wave antenna for series superconducting detectors of the disclosure has following technical effects:

1. The embedding meander of the disclosure can be connected to a plurality of the detectors with low impedance, and the performance of the traveling-wave antenna is not affected while the target impedance matching is completed.

2. The disclosure increases the working bandwidth of the THz antenna embedded with the series detectors.

### BRIEF DESCRIPTION OF DRAWINGS

FIG. 1 illustrates a schematic structural diagram of a meander embedding sector traveling-wave antenna for series superconducting detectors according to an embodiment of the disclosure.

FIG. 2 illustrates another schematic structural diagram of the meander embedding sector traveling-wave antenna for series superconducting detectors according to the embodiment of the disclosure.

FIG. 3 illustrates simulated active reflection coefficients of the sector antenna embedded with a meander series of seven Josephson junctions according to an embodiment of the disclosure.

FIG. 4 illustrates a simulated radiation pattern of the sector antenna embedded with a meander series of seven Josephson junctions at 262 gigahertz (GHz) according to an embodiment of the disclosure.

Description of reference numerals:

1-low-impedance detector array; 1-1-first low-impedance detector; 1-2-second low-impedance detector; 1-3-third low-impedance detector; 1-4-fourth low-impedance detector;

1-5-fifth low-impedance detector; 1-6-sixth low-impedance detector; 1-7-seventh low-impedance detector; 2-meander metal layer; 2-1-first meander; 2-2-second meander; 2-3-third meander; 2-4-fourth meander; 2-5-fifth meander; 2-6-sixth meander; 3-bend-line metal layer; 4-sector metal layer.

### DETAILED DESCRIPTION OF EMBODIMENTS

Further explanation of the disclosure is described in detail below with reference to attached drawings. Therefore, those skilled in the art can understand the disclosure more deeply and can implement the disclosure, but the following is merely used to explain the disclosure with reference to illustrated embodiments, which is not limited to the disclosure.

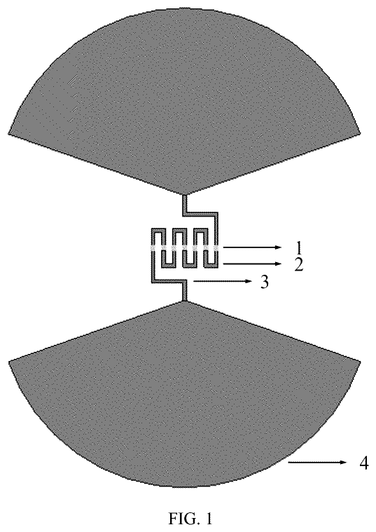

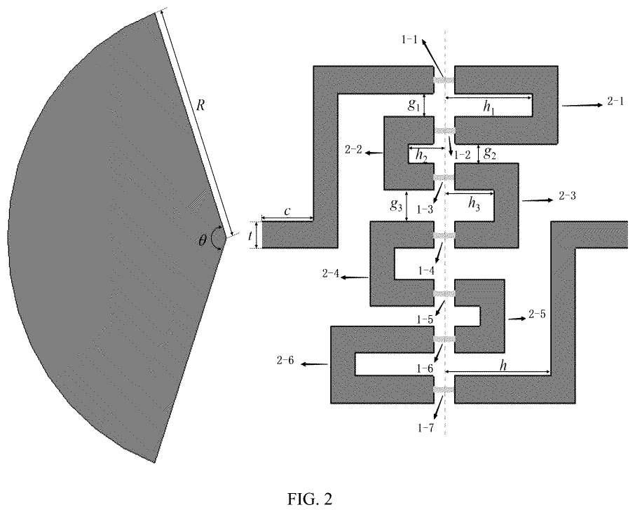

As shown in FIG. 1 to FIG. 2, a meander embedding sector traveling-wave antenna for series superconducting detectors includes a low-impedance detector array 1 (also referred to a detector array), a meander metal layer 2, a pair of bend-line metal layers 3, and a pair of sector metal layers 4. The low-impedance detector array 1 is individually connected in the meander metal layer 2 and the pair of bend-line metal layers 3. The pair of bend-line metal layers 3 is correspondingly connected to the pair of sector metal layers 4. The pair of sector metal layers 4 is disposed symmetrically centered on the low-impedance detector array 1.

The low-impedance detector array 1 includes: a first low-impedance detector 1-1 (also referred to a first detector), a second low-impedance detector 1-2, a third low-impedance detector 1-3, a fourth low-impedance detector 1-4, a fifth low-impedance detector 1-5, a sixth low-impedance detector 1-6, and a seventh low-impedance detector 1-7.

The meander metal layer 2 includes: a first meander 2-1, a second meander 2-2, a third meander 2-3, a fourth meander 2-4, a fifth meander 2-5, and a sixth meander 2-6. An end of the first low-impedance detector 1-1 (also referred to a right end of the first low-impedance detector 1-1) is connected to an end of the first meander 2-1 (also referred to an upper end of the first meander 2-1), and another end of the first meander 2-1 (also referred to a lower end of the first meander 2-1) is connected to an end of the second low-impedance detector 1-2; another end of the second low-impedance detector 1-2 is connected to an end of the second meander 2-2, and another end of the second meander 2-2 is connected to an end of the third low-impedance detector 1-3; another end of the third low-impedance detector 1-3 is connected to an end of the third meander 2-3, and another end of the third meander 2-3 is connected to an end of the fourth low-impedance detector 1-4; another end of the fourth low-impedance detector 1-4 is connected to an end of the fourth meander 2-4, and another end of the fourth meander 2-4 is connected to an end of the fifth low-impedance detector 1-5; another end of the fifth low-impedance detector 1-5 is connected to an end of the fifth meander 2-5, and another end of the fifth meander 2-5 is connected to an end of the sixth low-impedance detector 1-6; another end of the sixth low-impedance detector 1-6 is connected to an end of the sixth meander 2-6, and another end of the sixth meander 2-6 is connected to an end of the seventh low-impedance detector 1-7; and another end of the first low-impedance detector 1-1 and another end of the seventh low-impedance detector 1-7 are respectively connected to the bend-line metal layers 3 in the pair of bend-line metal layers 3.

The first meander 2-1 to the sixth meander 2-6 is individually a concave meander. Moreover, lengths and widths of the first meander 2-1 to the sixth meander 2-6 are unequal to each other. By adjusting the lengths of the first meander 2-1 to the sixth meander 2-6 to adjust their active impedances, low-impedance matching of the sector traveling-wave antenna with the first low-impedance detector 1-1 to the seventh low-impedance detector 1-7 is completed. In addition, an impedance of each of the first low-impedance detector 1-1 to the seventh low-impedance detector 1-7 is 15 omegas(Ω).

The sector antenna of the disclosure works in a traveling-wave mode. The traveling-wave sector antenna of the disclosure is suitable for any low-impedance terahertz (THz) detector. The disclosure designs the THz broadband antenna with a low input-impedance excited by multiple sources in view of the series THz detectors. A plurality of the low-impedance detectors are embedded in the antenna of the disclosure to complete impedance matching without affecting the performance of the antenna. In an illustrated embodiment of the disclosure, a total length of the meander mental layer 2 can be adjusted at will, thereby accommodating the low-impedance detectors according to requirements. Furthermore, the length and spacing within the meander mental layer 2 can be adjusted to determine the number of the accommodated series detectors, and a length of each of the pair of sector metal layers 4 can be adjusted, thereby to determine the working frequency of the sector antenna. When the THz sector antenna is placed on a substrate with a thick dielectric, a surface wave effect of the THz sector antenna can be eliminated by placing a silicon super-hemispherical lens or an electromagnetic band gap (EBG) attached to the back of the substrate.

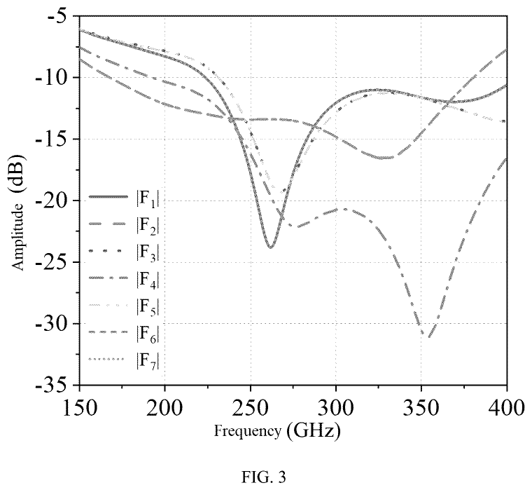

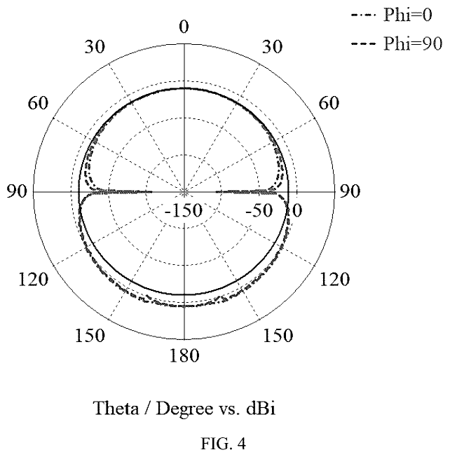

In computer simulation technology (CST) simulation software, the sector antenna is made of an ideal conductor and the sector antenna is placed on a magnesium oxide (MgO) substrate (with a relative dielectric constant of 9.6). And then, the detectors are respectively represented by discrete ports of 15 Ω to perform multi-port active simulation, and the discrete ports in the embedding meander can be increased or decreased according to practical requirements. When parameters of the antenna are as follows: R=212 micrometers (μm), θ=142° , t=4 μm, c=14 μm, g₁=g₂=g₃=4 μm, h₁=h₃=9 μm, h₂=10 μm, and h=15 μm,the active reflection coefficients of the seven active ports under the excitation and the radiation pattern at 262 gigahertz (GHz) are shown in FIG. 3 and FIG. 4, respectively. The matching bandwidth of 10 decibel (dB) is at a range from 232 GHz to 381 GHz, i.e., the relative bandwidth reaches 48.6%, and the directivity reaches 7.38 dBi (referred to a unit for power gain of the antenna).

The objectives, technical solutions and beneficial effects of the disclosure are further described in detail above, and it should be understood that the foregoing is merely the illustrated embodiment of the disclosure and is not intended to limit the scope of the disclosure. Therefore, equivalent variations and modifications made by those skilled in the related art without departing from the concept and principle of the disclosure fall within the scope of the protection of the disclosure.

What is claimed is:

1. A meander embedding sector traveling-wave antenna, comprising: a detector array, a meander metal layer, a pair of bend-line metal layers, and a pair of sector metal layers; and
wherein the detector array is individually connected in the meander metal layer and the pair of bend-line metal layers; the pair of bend-line metal layers is correspondingly connected to the pair of sector metal layers; and the pair of sector metal layers is disposed symmetrically centered on the detector array.

2. The meander embedding sector traveling-wave antenna as claimed in claim 1, wherein the detector array comprises: a first detector, a second detector, a third detector, a fourth detector, a fifth detector, a sixth detector, and a seventh detector;
wherein the meander metal layer comprises: a first meander, a second meander, a third meander, a fourth meander, a fifth meander, and a sixth meander; and
wherein an end of the first detector is connected to an end of the first meander, and another end of the first meander is connected to an end of the second detector; another end of the second detector is connected to an end of the second meander, and another end of the second meander is connected to an end of the third detector; another end of the third detector is connected to an end of the third meander, and another end of the third meander is connected to an end of the fourth detector; another end of the fourth detector is connected to an end of the fourth meander, and another end of the fourth meander is connected to an end of the fifth detector; another end of the fifth detector is connected to an end of the fifth meander, and another end of the fifth meander is connected to an end of the sixth detector; another end of the sixth detector is connected to an end of the sixth meander, and another end of the sixth meander is connected to an end of the seventh detector; and another end of the first detector and another end of the seventh detector are respectively connected to the bend-line metal layers in the pair of bend-line metal layers.

3. The meander embedding sector traveling-wave antenna as claimed in claim 2, wherein each of the first meander to the sixth meander is a concave meander; and lengths and widths of the first meander to the sixth meander are unequal to one another.

4. The meander embedding sector traveling-wave antenna as claimed in claim 3, wherein the lengths of the first meander to the sixth meander are configured to be adjusted to adjust active impedances of the first meander to the sixth meander and to complete target impedance matching with the first detector to the seventh detector.

5. The meander embedding sector traveling-wave antenna as claimed in claim 4, wherein an impedance of each of the first detector to the seventh detector is 15 Ω.
